(19) United States
(12) Patent Application Publication
(10) Pub. No.: US 2008/0094082 A1
(43) Pub. Date: Apr. 24, 2008

(54) Die Infrared Transceiver Bus

(75) Inventor: Steven A. Kummerl, Carrollton, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/958,533

(22) Filed: Dec. 18, 2007

Related U.S. Application Data
(62) Division of application No. 10/946,820, filed on Sep. 22, 2004.

(51) Int. Cl. G01R 31/26

(52) U.S. Cl. 324/752

(57) ABSTRACT

A semiconductor wafer adapted to wirelessly transfer data to a testing system. The wafer comprises a plurality of dies, each die adjacent another die and each die comprising an infrared transceiver. A first infrared transceiver transfers data to a second infrared transceiver by emitting a pattern of infrared light pulses representative of the data.

### BACKGROUND

Integrated circuits are fabricated on the surface of a semiconductor wafer in layers and later singulated into individual semiconductor devices, or “dies.” Since the material of a semiconductor wafer—commonly silicon—tends to be relatively fragile and brittle, a die (also called a “chip”) is often encapsulated in a protective housing or “package” to permit subsequent handling of the die such as for mounting on a circuit board.

Because each die may be able to perform any of a variety of tasks, a package containing multiple dies may have increased functionality over a package containing only one die. Such dies contained in a single package generally are stacked adjacent each other and are called “stacked dies.” Packages containing stacked dies are called “stacked die packages.” In a stacked die package, two or more semiconductor dies are electrically connected using bond wires by arranging each die on top of another die.

Prior to wafer singulation, the dies on a wafer are tested for proper functionality. Wafer testing is performed using conventional probing techniques, which are often expensive and time-consuming. Dies produced by way of wafer singulation may be stacked to form stacked die packages, as described above. However, besides substantially adding to overall production costs, the bond wires used to couple these stacked dies often carry considerable wire inductance, which negatively affects signal/data integrity.

### SUMMARY

The problems noted above are solved in large part by a stacked die infrared transceiver bus. One exemplary disclosed embodiment is a semiconductor stacked die package adapted to wirelessly transfer data between the dies stacked in the package. The package comprises a plurality of dies, each die adjacent another die and each die comprising an infrared transceiver. A first infrared transceiver transfers data to a second infrared transceiver by emitting a pattern of infrared light pulses representative of the data.

Another exemplary disclosed embodiment comprises an infrared semiconductor wafer testing system comprising a processor coupled to an infrared testing transceiver, said infrared testing transceiver adjacent a wafer comprising a plurality of dies, at least some of said dies comprising infrared transceivers. The processor may verify the functional integrity of at least some of the dies by emitting a pattern of infrared light pulses representative of electrical test signals, and decoding into electrical result signals a second pattern of infrared light pulses received from a die, wherein the second pattern of infrared light pulses is representative of results produced by the die.

Yet another exemplary embodiment comprises a method of testing semiconductor wafer using infrared transceivers comprising emitting from a testing apparatus a pattern of infrared light pulses, said pattern of infrared light pulses representative of electrical test signals, decoding on a wafer die the pattern of infrared light pulses into electrical signals, processing on the wafer die the electrical signals to produce results, and transmitting the results to the testing apparatus by emitting a second pattern of infrared light pulses.

### BRIEF DESCRIPTION OF THE DRAWINGS

For a detailed description of exemplary embodiments of the invention, reference will now be made to the accompanying drawings in which:

FIG. 1 shows an infrared transceiver and a related illumination field, in accordance with various embodiments of the invention;

FIG. 2 shows multiple infrared transceivers and related illumination fields, in accordance with various embodiments of the invention;

FIG. 3a shows stacked dies comprising infrared transceivers and bond wire power connections;

FIG. 3b shows another preferred stacked die configuration, each die comprising a plurality of infrared transceivers and bond wire connections, in accordance with some embodiments of the invention;

FIG. 4 shows a package comprising stacked die, the stacked die in communication with each other by way of infrared transceiver buses, in accordance with embodiments of the invention;

FIG. 5 shows a preferred infrared transceiver comprising a transmitter having a light source and a receiver having a photodiode, in accordance with embodiments of the invention;

FIG. 6a shows a semiconductor wafer comprising multiple dies, in accordance with preferred embodiments of the invention;

FIG. 6b shows a detailed view of the dies of FIG. 6a;

FIG. 6c shows an infrared transceiver wafer-testing configuration;

FIG. 6d shows another infrared transceiver wafer testing configuration comprising multiple stacked wafers, in accordance with various embodiments of the invention; and

FIG. 7 shows a preferred process that may be used to test the stacked wafers.

### NOTATION AND NOMENCLATURE

Certain terms are used throughout the following description and claims to refer to particular system components. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect or direct electrical connection. Thus, if a first device couples to a second device, that connection may be through a direct electrical connection, or through an indirect electrical connection via other devices and connections.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Presented herein is a network of infrared transceivers arranged on stacked dies such that data may be transferred between two or more dies by way of the infrared transceivers (i.e., a transceiver bus). Various embodiments of the invention are made possible at least in part by the realization that infrared light with a wavelength between approximately 770 nm and 1 mm may successfully pass through silicon or gallium arsenide semiconductor material such that the infrared light, when encoded with data as described below, may be accurately decoded after passing through such material. Because wafers/dies are made with such semiconductor materials, infrared light may pass through the wafers/dies. Each transceiver may transfer information to another transceiver by converting data (i.e., electrical signals) into a pattern of infrared light pulses and emitting this pattern of infrared light pulses to the other transceiver. Likewise, a transceiver may receive information from another transceiver by monitoring the light pattern emitted by the other transceiver and decoding the light pattern into data. In this way, information is transmitted among stacked dies throughout the stacked die package. Because the need for bond wires is reduced or eliminated, wire inductance and costs also may be reduced. Furthermore, such infrared transceiver configurations may be used to test the functional integrity of one or more wafers, thereby reducing or eliminating the need for costly and time-consuming probe tests.

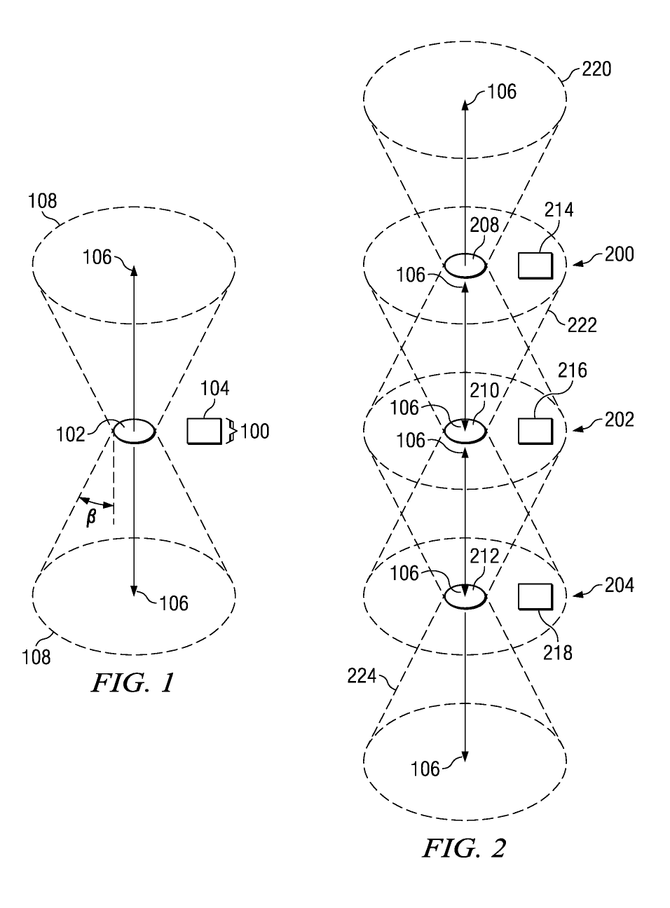

FIG. 1 shows an exemplary infrared transceiver 100 comprising an infrared transmitter 102 and an infrared receiver 104. The infrared transmitter 102 may be any optical transmitter that emits infrared light that is suitable for application as disclosed herein. The angle at which the transmitter 102 emits light may be controlled using any suitable means, such as by a manufacturer. The infrared transmitter 102 transmits infrared light in substantially vertical directions, as indicated by the arrows 106. The infrared light emitted by the transmitter 102 spreads in each vertical direction at an angle β (where angle β is adjustable), thus establishing an illumination field 108. As mentioned above, the transmitter 102 intermittently emits infrared light (i.e., in patterns). These infrared light patterns represent various data to be transmitted between two transceivers. The light patterns may be encoded using header information at the beginning of the data stream to determine for which transceiver the data was intended and also to determine if information was lost during transmission. Any receiver 104 located in the illumination field 108 may receive these infrared light patterns and decode the patterns into data. The receiver 104 shown in FIG. 1 is not in the illumination field 108 of transmitter 102 and thus is incapable of receiving and decoding the light pattern. The transmitter 102 may emit light using, among other things, a light source such as a light-emitting-diode (“LED”), light amplification by the stimulated emission of radiation (“LASER”), and/or vertical cavity surface emitting laser (“VCSEL”).

FIG. 2 shows multiple infrared transceivers 200-204, each comprising a transmitter 208-212 and a receiver 214-218, respectively. As in FIG. 1, each transmitter 208-212 transmits infrared light in opposite vertical directions, as indicated by arrows 106. The infrared light transmitted by the transmitters 208-212 covers illumination fields 220-224, respectively. The receiver 214 is in the illumination field 222. The receiver 216 is in the illumination fields 220, 224, and the receiver 218 is in the illumination field 222. As such, information may be directly transmitted from the transmitter 208 to the receiver 216, the transmitter 210 to the receivers 214, 218, and the transmitter 212 to the receiver 216, by way of the infrared light patterns discussed above.

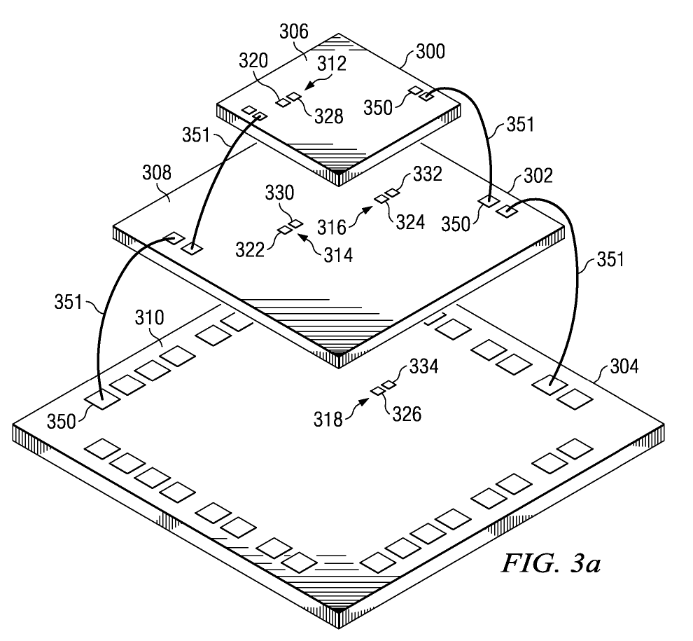

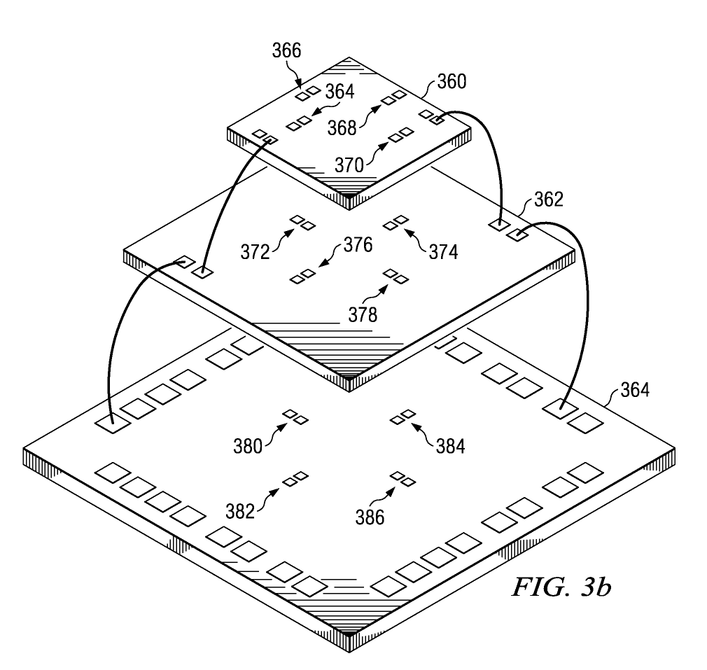

FIG. 3a shows a plurality of dies 300-304 stacked adjacent each other. The dies 300-304 preferably are made with either silicon or gallium arsenide, although any suitable material may be used. Each die 300-304 comprises an active surface 306-310, respectively. Each active surface 306-310 comprises the circuitry of a corresponding die 300-304 which is used to perform the various functions of the die 300-304. The active surface 306 may comprise a transceiver 312 having a transmitter 320 and a receiver 328. The active surface 308 may comprise transceivers 314-316 having transmitters 322, 324 and receivers 330, 332, respectively. The active surface 310 may comprise a transceiver 318 having a transmitter 326 and a receiver 334.

As discussed above, the transmitters 320-326 are used to convert electrical signals (i.e., data) into a pattern of infrared light pulses. The transmitters 320-326 may transfer this data to receivers 328-334 by emitting the pattern of infrared light pulses. In turn, any receiver 328-334 that, by virtue of location and transmission angle β (where angle β is adjustable), is capable of detecting the pattern of infrared light pulses may receive the pattern and convert the pattern into electrical signals. In this way, the dies 300-304 may transfer data between each other.

For example, the die 300 may have data that is to be transferred to the die 304. Accordingly, the die 300 may route the data to the transceiver 312 on the active surface 306 of the die 300. The transmitter 320 then may convert the electrical data signals into a pattern of infrared light pulses and subsequently may emit this pattern of infrared lights. Because the pattern of lights is emitted at a wavelength between approximately 1 mm and 770 nm, the lights penetrate through the die 300 to the transceiver 314 on the die 302. The receiver 330 of the transceiver 314 may read the pattern of infrared lights emitted by the transmitter 320 and convert the pattern into electrical data signals. The data signals then may be routed across the active surface 308 of the die 302 to the transceiver 316. The transmitter 324 of the transceiver 316 may convert the data signals into a pattern of infrared light pulses and then may emit the lights. As previously mentioned, because the infrared lights fall into an approximate wavelength range of 1 mm to 770 nm, the infrared lights may pass through the die 302.

Because the lights from the die 300 to the die 304 pass through the die 302, the receiver 334 of the transceiver 318 on the die 304 may read the pattern of infrared light pulses emitted by the transmitter 324 and convert the pattern of lights into an electrical data signal representative of the electrical data signal originally emitted by the transceiver 312 of the die 300. In this way, data is successfully transmitted from the die 300 to the die 304. As discussed above, to ensure that a transmitter 320-326 does not emit light at a power level that causes the light to travel past an intended receiver 328-334 or oversaturate a receiver beyond its operating power range, the power level of a light source (e.g., LED, LASER, VCSEL) on the transmitters 320-326 may be adjusted using any suitable technique, such as by adjusting the voltage level of the transmitters 320-326. The power level also may be adjusted based on other factors of concern, such as light dispersion and/or absorption by epoxy or molding, receiver sensitivity and location, and/or any other such factors. Such adjustments may be performed in any embodiment of the invention.

Each of the dies 300-304 may comprise a plurality of bond pads 350. At least some of the bond pads 350 are used for transferring ground and power connections from a package containing the dies 300-304 to each of the dies 300-304. In at least some embodiments, because data transfer between the dies 300-304 is performed by the infrared transceivers 312-318, bond wires 351 on the dies 300, 302 are used to provide power and ground connections. Bond wires on the die 304 may be used to transfer electrical data signals, as well as power and ground signals, from the active surface 310 of the die 304 to the package containing the dies 300-304.

In the stacked die configuration of FIG. 3a, no more than one receiver is in the illumination field of any transmitter. Thus, only one receiver reads the infrared light patterns emitted by a transmitter. However, in some embodiments (e.g., applications requiring high-precision or fine-pitch connections), multiple receivers may fall into the illumination field of a transmitter. In such cases, it is necessary for the transmitter to specify the receiver for which the transmitted data is intended. Accordingly, a transmitter may transmit a header, or preamble, prior to data transmission. Like the data transmission, the header may be in the form of a predetermined pattern of infrared light pulses. Prior to reading the data transmission, each receiver in the illumination field of the transmitter reads the header. The receiver(s) for which the data transmission is intended recognizes the header and reads the data transmission. Receiver(s) for which the data transmission is not intended may read the header and, not recognizing the header, may not read the subsequent data transmission.

For example, FIG. 3b shows a stacked die configuration substantially similar to that shown in FIG. 3a. However, each stacked die 360-364 shown in FIG. 3b comprises multiple transceivers. Specifically, the die 360 comprises transceivers 364-370, the die 362 comprises transceivers 372-378, and the die 364 comprises transceivers 380-386. The transceivers may be arranged in any suitable fashion. At least some of the transceivers 364-386 fall into the illumination fields of each other (i.e., more than one transceiver may fall into the illumination field of another transceiver). For example, the transceivers 372, 374 may fall into the illumination field of the transceiver 368. Likewise, the transceivers 380-384 and 364-368 may fall into the illumination field of the transceiver 372. As mentioned above, transceivers transmitting data may transmit a header or some other identifying information prior to a data transmission, so that the data is transmitted to the proper receiving transmitter.

In the preceding example, the transceiver 376 may emit an infrared light in a predetermined pulsing pattern. Several of the transceivers 364-386 may fall into the illumination field of the transceiver 376. Each such transceiver is capable of reading the data transmission. However, only certain transceivers are the intended recipients of the data transmission. As such, a header (i.e., a predetermined series of infrared light pulses emitted prior to the series of infrared light pulses representative of the data transmission) is emitted prior to the data transmission. Each possible receiving transceiver may have a copy of the header or some other identifying information that pertains only to that transceiver. Thus, each receiving transceiver may read and decode the header emitted by the transceiver 376 into electrical signals. Each receiving transceiver then may compare the electrical signals of the emitted header to the header or other identifying information pertaining to that receiving transceiver. If the headers match, the transceiver may read the subsequent data transmission and process the data accordingly. If there is no match, the transceiver may not read the subsequent data transmission.

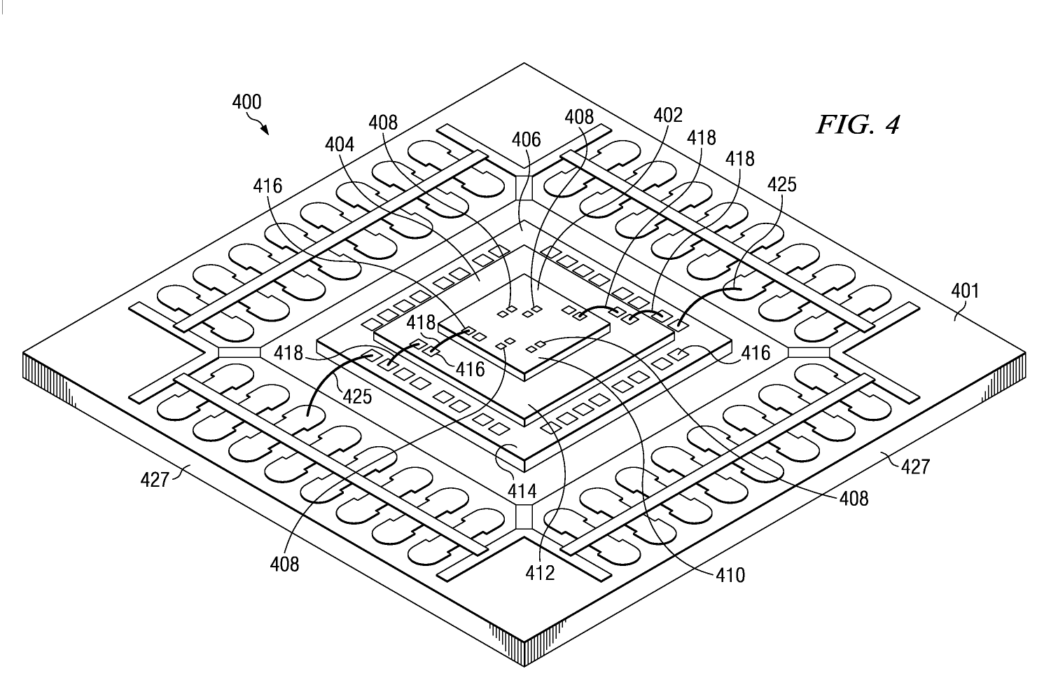

FIG. 4 shows a package 400 comprising a lead frame 401 and stacked dies 402-406 adjacent the lead frame 401. Epoxy (not shown) may be fixed between or around two or more of the dies 402-406, thus providing an additional way to control light dispersion and also to occupy space between the dies to prevent undesirable materials (e.g., debris) from accumulating in this space. The epoxy/mold compound or other materials sandwiched between the dies (e.g., spacers or adhesive tapes) may be used to intentionally block, attentuate, and/or transmit infrared signals, depending on the materials selected. Each of the stacked dies 402-406 may comprise multiple infrared transceivers 408 on active surfaces 410-414, respectively (the transceivers 408 on the dies 404, 406 are not visible in the figure). Each of the dies 402-406 comprises multiple bond pads 416. As mentioned above, because data transfer between the dies 402-406 is performed using the infrared transceivers 408, bond wires 418 are necessary only to provide power and ground connections to the dies 402, 404, although bond wires may be used as desired and for any reason. Specifically, two bond wires 418 may be used to electrically connect the lead frame 401 to two bond pads 416 on the die 406. One of these connections may be a power source and the other connection may be a ground connection. The die 406 may use the power and ground connections as necessary. The die 406 also may provide the power and ground connections to the adjacent die 404 by way of bond wires 418 and the bond pads 416, as shown. The die 404 may use the power and ground connections as necessary. The die 402 also may use the power and ground connections by coupling with the bond pads 416 of the die 404 using bond wires 418, as shown. In this way, power and ground connections are supplied to the dies 402-406.

As previously mentioned, the infrared transceivers 408 may be used to transfer information between the dies 402-406. Bond wires 425 may be used to transfer information between the die 406 and the lead frame 401. In turn, the lead frame 401 may be electrically coupled to a circuit board 427 or some other device external to the package 400. In this way, an indirect electrical connection is established between the circuit board 427 and each of the dies 402-406. For example, the die 402 may transmit electrical data signals to the circuit board 427 by using either of the techniques described above in context of FIGS. 3a and 3b. Specifically, in at least some embodiments, a transceiver 408 on the die 402 may convert the electrical data signals into a series of infrared light pulses and subsequently may emit this series of lights. A transceiver 408 on the die 404 may read the series of lights. If multiple transceivers 408 are in the illumination field of the transceiver 408 of the die 402, then a header may be used, as described above, to specify the intended recipient transceiver 408 on the die 404.

The transceiver 408 on the die 404 that reads the data transmission then may convert the series of infrared light pulses to an electrical data signal. The electrical data signal may be routed to another transceiver 408 on the die 404, converted again to a series of infrared light pulses, and emitted from the transceiver 408. A transceiver 408 on the die 406 may read the data transmission and convert the series of infrared light pulses into electrical data signals. The electrical data signals then may be routed across an active surface 414 of the die 406 to the bond pads 416. The electrical data signals then may be transmitted from the bond pads 416 to the lead frame 401 by way of bond wires 425, and from the lead frame 401 to the circuit board 427. Thus, data is transmitted from the die 402 to the circuit board 427. Using such transceiver buses, data may be transmitted throughout the package 400 and/or the circuit board 427.

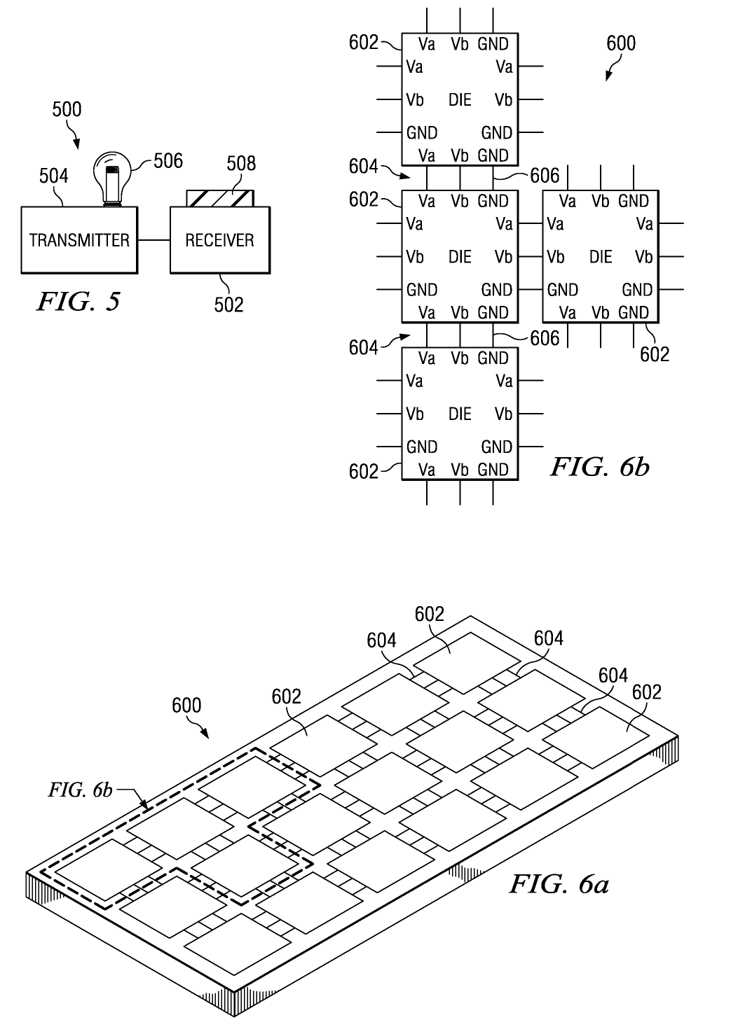

FIG. 5 shows the infrared transceivers of FIGS. 1-4 in greater detail. An infrared transceiver 500 may comprise a receiver circuit 502 and a transmitter circuit (i.e., “driver”) 504. The receiver circuit 502 may comprise a photodiode (e.g., a P-intrinsic-N, or PIN, photodiode) 508 and the transmitter circuit 504 may comprise an adjustable light source 506 (e.g., VCSEL, LED, LASER). The adjustable light source 506 may be adjustable in terms of power level, wavelength and/or frequency of light, and angle of light emission. The transmitter circuit 504 converts electrical data signals into a pattern of infrared light pulses, as described above. The external light source 506 emits the pattern of infrared light pulses. The photodiode 508 of the receiver circuit 502 reads light signals from the light source 506 (in this case, the light emitted from the light source of another infrared transceiver) and the receiver circuit 502 outputs voltage or current representative of the pattern of light signals.

Although not required, in at least some embodiments, the receiver circuit 502 and the transmitter circuit 504 may be fabricated on a single integrated circuit. In other embodiments, portions of the receiver circuit 502 (e.g., the photodiode 508) may be fabricated abutting a package substrate that also abuts an integrated circuit comprising remaining portions of the receiver circuit 502 and the transmitter circuit 504. The entire package may be encapsulated in a molding material (e.g., plastic) to form a discrete transceiver module. The transceiver module then may be fixed abutting a die, as described above. In still other embodiments, a transceiver may be fabricated (i.e., “grown”) directly on a die, instead of first forming a discrete transceiver module. These or any of a variety of techniques may be used to fabricate any of a variety of infrared transceivers, any of which may be used in the various embodiments described herein.

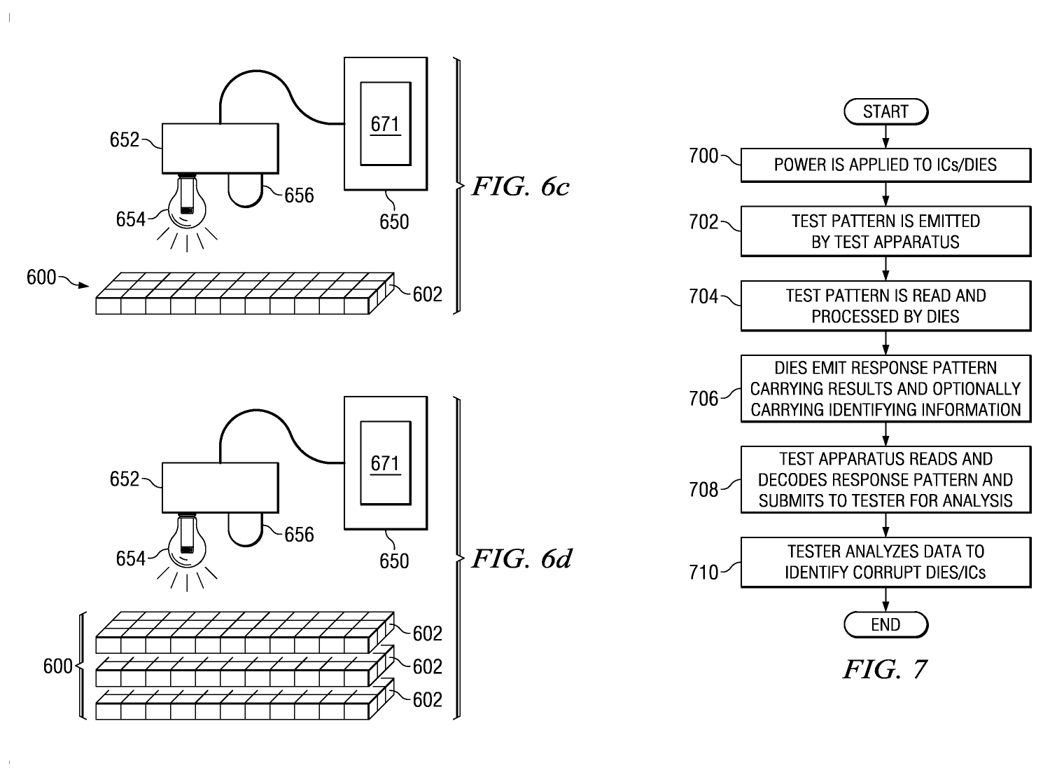

In addition to transferring data between dies, the infrared transceiver configuration described above also may be used to test one or more wafers for proper functional integrity, as described in context of FIGS. 6a-6d and 7. Specifically, FIG. 6a shows a wafer 600 comprising a plurality of dies 602. The dies 602 are separated from each other on the wafer 600 by scribe streets 604 situated therebetween. FIG. 6b shows the dies 602 of FIG. 6a in detail. The dies 602 are to be tested for functional integrity by way of “wafer testing,” wherein some or all of the dies 602 on the wafer 600 are tested simultaneously. Although the dies 602 are to be wafer tested using infrared transceivers as described below, the dies 602 may still require a power source, because the infrared signals the dies 602 receive may provide only test signal data. The dies 602 must be provided with power to process such test signal data. Accordingly, at least some of the dies 602 may be provided with power (e.g., a ground connection and one or more voltage connections) from another die 602 (block 700) by way of copper traces 606 that are run through scribe streets 604 (i.e., a “daisy chain” link is used to provide at least some of the dies 602 with multiple voltage and a ground connection). Although voltage connections VA, VB and ground connection GND are shown, any number of voltage and/or ground connections may be provided, depending on specific application requirements. In other embodiments, voltage and/or ground connections may be provided to some or all of the dies 602 by way of a power apparatus having a plurality of metal leads (not shown), where the power apparatus is coupled to a voltage and/or ground source. The metal leads may be coupled to the voltage and ground connections of some or all of the dies 602, thus providing voltage and ground connections to the dies 602 by way of the metal leads.

After some or all of the dies 602 have been provided with appropriate power supplies, testing data may be transmitted between a tester and the dies 602 to verify the functional integrity of the dies 602. Specifically, FIG. 6c shows a tester 650 (e.g., a computer) comprising a processor 671 and coupled to a transceiver testing apparatus 652 comprising an infrared light source 654 (e.g., an LED, LASER or VCSEL) and an infrared camera 656 (e.g., photodiode). The testing apparatus 652 may be positioned adjacent (e.g., above) the wafer 600 comprising a plurality of dies 602. The tester 650 (i.e., the processor 671) then may fabricate a testing sequence that is transferred to the testing apparatus 652. In turn, the testing apparatus 652 may cause the infrared light source 654 to begin pulsing a pattern of infrared lights (“test pattern”) such that some or all of the dies 602 may detect and read the test pattern (block 702). Each of the dies 602 may comprise a transceiver (as shown in FIGS. 3a, 3b and 4), each transceiver comprising a transmitter with a light source and a receiver with a photodiode. As such, each of the dies 602 may read the test pattern (block 704) by way of a corresponding photodiode and process the test pattern.

During processing, a die 602 may decode or otherwise convert the test pattern to electrical signals. These electrical signals may be used by the die 602 to perform the function the die 602 is designed to perform. After performing such a function using the electrical signals, the die 602 may produce results. These results may be converted from electrical signals into a response pattern of infrared light pulses. Each die 602 may emit such an infrared response pattern by way of the light source (block 706) such that the infrared camera 656 may detect and read the response pattern. In at least some embodiments, such as those comprising multiple stacked wafers 600 as shown in FIG. 6d, a response pattern may comprise identifying information (e.g., a header as discussed above) that may enable the testing apparatus 652 to determine the die 602 from which the response pattern was sent. In addition to the test results mentioned above, the response pattern also may comprise any other suitable information pertaining to the wafer testing process.

After using the infrared camera 656 to detect and read the response patterns emitted by the various dies 602, the testing apparatus 652 may convert the patterns into electrical signals and transfer the electrical signals to the tester 650 (block 708). Thereafter, the tester 650 may analyze the signals to determine which of the dies 602 functions properly and which of the dies 602 functions improperly (block 710). For example, the tester 650 may compare the electrical signals with expected results to determine whether a match exists. A match may indicate a functionally competent die 602; conversely, a mismatch may indicate a corrupt die 602. Alternatively, the tester 650 may evaluate the wafer test using any appropriate technique. Because such infrared testing minimizes the need for traditional probe testing, testing costs and time consumption are reduced in comparison to the testing costs and time consumption associated with traditional probe testing. Also, because the use of bond wires is minimized, costs and problems associated with wire inductance also are minimized.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A semiconductor wafer testing system, comprising:
a processor;
an infrared source coupled to the processor, operable to transmit a first pattern of infrared pulses to a field of a plurality of dies on a semiconductor wafer, each die having an infrared receiver and an infrared transmitter, the infrared receiver operable to decode the first pattern of infrared pulses and a circuitry operable to generate an electric signal in response to the decoded first pattern of infrared pulses and to convey the electric signal to the infrared transmitter operable to generate a second pattern of infrared pulses in response to the electric signal;
a camera coupled to the processor operable to capture the second pattern of infrared pulses from a field of plurality of dies; and
the processor operable to decode the second pattern of infrared pulses and recognize a functionality of a die.

2. The system of claim 1, wherein the first pattern and the second pattern of infrared light pulses comprises a header containing identifying information.

3. The system of claim 3, wherein the processor uses the identifying information to identify a defective die.

4. The system of claim 1, wherein the infrared lights have a wavelength that can be absorbed by the semiconductor material to generate an electric signal.

5. The system of claim 1, further comprising a power supply communicative to the dies on the wafer via copper traces.

6. The system of claim 1, wherein the infrared receiver comprises a p-n junction or a p-i-n junction, which converts the infrared light pulses into the electric signal.

7. The system of claim 1, wherein the infrared transmitters comprise a light source selected from a group consisting of an LED, a VCSEL and a LASER.

8. A semiconductor wafer adapted to be testable on a system in claim 1.

9. A method of testing semiconductor wafer, comprising the steps of:
providing a processor;
providing an infrared source coupled to the processor;
providing a semiconductor wafer;
transmitting a first pattern of infrared pulses to a field of a plurality of dies on the semiconductor wafer, each die having a circuitry, an infrared receiver, and an infrared transmitter;
the infrared receiver decoding the first pattern of infrared pulses;
the circuitry generating an electric signal in response to the decoded first pattern of infrared pulses and conveying the electric signal to the infrared transmitter;
the infrared transmitter generating a second pattern of infrared pulses in response to the electric signal;
directing the second pattern of infrared pulses to a camera coupled to the processor;
the camera capturing the second pattern of infrared pulses from a field of plurality of dies; and
the processor processing information in the captured the second pattern of infrared pulses and identifying functional dies on the wafer.

10. The method of claim 9, in which the second pattern of infrared light pulses comprises die identifying information.

11. The method of claim 9, in which transmitting the first pattern of infrared light pulses comprises using infrared light at a wavelength between and including approximately 1 millimeter and 770 nanometers, so the light pulses are absorbable by a p-n junction or a p-i-n junction in the infrared receivers and converted into the electric signal.

12. The system of claim 1, in which the field comprises every die on the wafer.

13. The method of claim 9, in which the field comprises every die on the wafer.
